(19) United States
(12) Patent Application Publication
(10) Pub. No.: US 2024/0075827 A1
(43) Pub. Date: Mar. 7, 2024

(54) ELECTRIC VEHICLE CHARGING APPARATUS

(71) Applicant: MODERNTEC CO., LTD., Gyeongsangnam-do (KR)

(72) Inventor: Seong Doo KIM, Gyeongsangnam-do (KR)

(21) Appl. No.: 18/273,622

(22) PCT Filed: Dec. 20, 2021
(86) PCT No.: PCT/KR2021/019427

§ 371 Date: Jul. 21, 2023

(30) Foreign Application Priority Data
Jan. 28, 2021 (KR) 10-2021-0012569

(51) Int. Cl. B60L 53/16; B60L 53/10; B60L 53/24

(52) U.S. Cl. CPC B60L 53/16; B60L 53/11; B60L 53/24; B60L 2210/10; B60L 2250/16; H01L 29/1608

(57) ABSTRACT

An electric vehicle charging apparatus may include an external connector that is connected to an electric vehicle of a user, and a relay mesh that supplies electricity to the external connector. The amount of output power supplied through the relay mesh may vary according to the user's selection of fast charging or slow charging. The relay mesh may include a SiC module, and the SiC module may have a SiC MOSFET module serving as a switch for the electricity supplied to the external connector, and a SiC drive module sending a driving signal for switching to the SiC MOSFET module.

### CROSS REFERENCE TO RELATED APPLICATIONS AND CLAIM OF PRIORITY

This application claims benefit under 35 U.S.C. 119, 120, 121, or 365(c), and is a National Stage entry from International Application No. PCT/KR2021/019427, filed Dec. 20, 2021, which claims priority to the benefit of Korean Patent Application No. 10-2021-0012569 filed in the Korean Intellectual Property Office on Jan. 28, 2021, the entire contents of which are incorporated herein by reference.

### BACKGROUND

### 1. Technical Field

The present disclosure relates to an electric vehicle charging apparatus designed to use a silicon carbide (SiC) MOSFET for electric vehicle charging.

### 2. Background Art

As part of the development of green technology, a growing body of research on electric vehicle (EV) charging systems, in addition to research on electric vehicles, to increase the usability of electric vehicles has been conducted. However, since the research and development is still ongoing, there remain technical problems that need to be solved, and charging systems that meet diverse consumer needs have not yet become widespread.

For mass dissemination of electric vehicles, it is necessary to reduce the relatively long charging time compared to the refueling time of vehicles using fossil fuels. To this end, high-speed switching devices based on silicon carbide (SiC) have recently gained attention.

### SUMMARY

The present disclosure has been made keeping in mind the problems occurring in the related art. An objective of the present disclosure is to provide an electric vehicle charging apparatus for fast electric vehicle (EV) charging. The apparatus may include a silicon carbide (SiC) MOSFET device capable of high-speed switching even in high power and high voltage environments.

In order to achieve the above mentioned objective, according to an embodiment of the present disclosure, there is provided an electric vehicle charging apparatus including: an external connector connected to an electric vehicle of a user; and a relay mesh configured to supply electricity to the external connector, wherein an amount of output power supplied through the relay mesh may vary depending on a user's selection of fast charging or slow charging.

The relay mesh may include a SiC module, wherein the SiC module may include: a SiC MOSFET module serving as a switch for electricity supplied to the external connector; and a SiC drive module sending a driving signal for switching to the SiC MOSFET module.

The SiC drive module may include: a digital isolator that physically separates the SiC drive module from other circuits; and a charge pump serving as a DC-DC converter.

The SiC MOSFET module may include: a heat sink that reduces heat loss from the SiC MOSFET module; a power connector to which electricity supplied to the external connector is connected; and a SiC MOSFET that is turned on when electricity is supplied to the external connector and turned off when not supplied, wherein the SiC MOSFET may use silicon carbide (SiC) as a semiconductor device material.

A display unit where the user selects fast charging or slow charging may be provided, wherein a signal according to the user's selection may be sent to a control board, and the control board may send an operation signal to the external connector selected by the user and a controller, wherein the controller may control the amount of power sent to the external connector by sending a trigger signal to the relay mesh according to the operation signal.

The relay mesh may be provided with a first SiC module and a second SiC module, wherein a power pack for supplying DC electricity for electric vehicle charging to the first SiC module and the second SiC module may be provided, and an array SiC module in which the first SiC module and the second SiC module are connected in parallel may be provided, wherein the array SiC module may output an integer multiple of an amount of power output from the first SiC module or the second SiC module, and an integer may be a positive natural number.

Compared to Si IGBTs, SiC MOSFETs can produce lower switching losses even at higher temperatures, which allows higher switching frequencies to be reached, resulting in a compact overall circuit. Moreover, since the SiC MOSFETs have high thermal resistance, their on-resistance can be maintained almost constant as the temperature rises.

As an electric vehicle charging apparatus of the present disclosure includes a silicon carbide (SiC) MOSFET, faster charging than current Si-based MOSFETs or IBGT modules is possible. Therefore, users can select fast or slow charging to suit their needs.

A fourth SiC MOSFET can be a spare SiC MOSFET in a first power pack, and a third SiC MOSFET can be a spare SiC MOSFET in a second power pack.

### BRIEF DESCRIPTION OF THE DRAWINGS

FIG. 1 shows a first SiC module or a second SiC module of the present disclosure;

FIG. 2 shows an array SiC module of the present disclosure;

FIG. 3 shows a SiC drive module of the present disclosure;

FIG. 4 shows a SiC MOSFET module of the present disclosure;

FIG. 5 shows an electric vehicle charging apparatus of the present disclosure; and

FIG. 6 is an enlarged view of part A shown in FIG. 5.

### DETAILED DESCRIPTION

For electric vehicle charging, metal oxide semiconductor field-effect transistors (MOSFET) or insulated gate bipolar transistors (IGBT) may be used.

However, rapid charging is vital for mass dissemination of electric vehicles, and for this purpose, a higher power, higher voltage device capable of high-speed switching is required.

To this end, it is necessary to utilize new materials to overcome the limitations of silicon devices. The new materials may include gallium arsenide (GaAs), a chemical compound of gallium and arsenic, gallium nitride (GaN), silicon carbide (SiC), and the like. Among the above new materials, devices based on SiC may be used.

SiC contains Si and C in a 1:1 ratio, with the Si and C atoms form very strong bonds, and may be thermally, mechanically, and chemically stable. Compared to an IGBT module using Si, a SiC module 200 based on SiC may significantly reduce unnecessary energy loss during power switching. In addition, the SiC module 200 may be miniaturized due to its low resistance, thereby enabling miniaturization of peripheral components, and a cooling mechanism such as a heat sink 420 may be simplified.

In the photovoltaic or electric vehicle industry, it is more likely to be exposed to a high voltage, high electric current, high power, high temperature environment, etc., and it is preferable to apply a material capable of stable high-speed switching even in such an environment.

Conductors, insulators, and semiconductors are classified on the basis of band gap, and the band gap is between the conduction band and the valence band, which are energy bands.

When the Fermi level (Fermi energy) where electrons can occupy with a 50% probability approaches the conduction band, electrons move easily inside a semiconductor, making the semiconductor behave like a conductor, whereas when the Fermi level is close to the valence band, it is easier for holes to move inside the semiconductor, making the semiconductor behave like an insulator. At this time, the Fermi level may shift towards to one of the energy bands under the influence of an external electric field, heat, etc., and the band gap may also be narrowed by heat. Accordingly, when silicon is exposed to a high voltage, high electric current, high power, high temperature environment, etc., silicon having a small band gap tends to become unstable, and for this reason, a material with a wide bandgap that is stable even at high temperatures may be required.

SiC has a bandgap three times wider than silicon, and may be less affected by electrons and bandgap changes caused by heat. In addition, SiC has a critical field, which means the strength of voltage that the material can withstand, about 10 times that of silicon, and thus SiC devices can operate at higher voltage without destroying the device. Moreover, since SiC has an electron saturation velocity that is about twice as fast as that of silicon, it is easy to manufacture devices capable of high-frequency operation with SiC. Furthermore, the thermal conductivity, a measure of heat release, of SiC is about 5 times that of silicon, and SiC can operate stably even in high-voltage or high-temperature environments.

That is, compared to Si IGBTs, a SiC MOSFET 410 may produce lower switching losses even at higher temperatures, which allows higher switching frequencies to be reached, resulting in a compact overall circuit. Moreover, since the SiC MOSFET has high thermal resistance, their on-resistance may be maintained almost constant as the temperature rises.

The on-resistance (Rds(on)) is the resistance that flows between the drain and the source of a MOSFET, that is, the resistance value between the drain and the source when the gate is ON, and may vary depending on the gate voltage. Normally, when the gate voltage is high, the on-resistance value is low, and may increase as the voltage between D-S increases. In a MOSFET, power loss can be expressed as an on-resistance, and the smaller the on-resistance value, the smaller the power loss during operation.

As an electric vehicle charging apparatus of the present disclosure includes a silicon carbide (SiC) MOSFET, faster charging than current Si-based MOSFETs or IBGT modules may be possible. A user may select fast charging at an additional cost or slow charging at relatively low cost depending on the setting of a prepared charging apparatus.

Referring to FIG. 1, the electric vehicle charging apparatus of the present disclosure may include a SiC relay, and the SiC relay may include a SiC drive module 300 that sends an on/off driving signal (S30) to a SiC MOSFET, and a SiC MOSFET module 400 provided with the SiC MOSFET 410. That is, a driving signal S30 may be sent from the SiC drive module 300 to the gate of the SiC MOSFET 410.

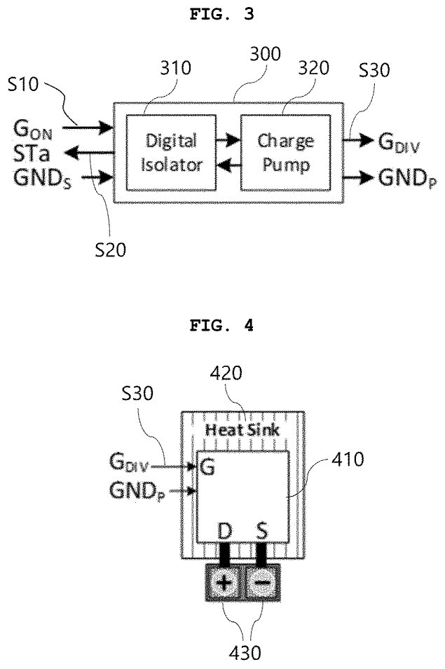

Referring to FIG. 3, the SiC drive module 300 may include a digital isolator 310 and a charge pump 320.

Most isolation isolators in circuits using DC electricity use galvanic isolation, which may be a circuit design technique that allows sub-circuits within a specific circuit to communicate with each other while preventing unwanted direct current from flowing in the middle. By using this technique, users or low voltage circuits can be protected from high voltage. Galvanic isolation means that no current flows between two circuits, but electrical signals or power may travel.

Methods such as capacitance, inductance, electromagnetic waves, light, sound, and mechanics may be used for galvanic isolation, and necessary parts may include photocouplers, transformers, relays, hall sensors, and the like.

A digital isolator 310 of the present disclosure may be a digital isolator that does not use an LED and a photo transistor. Thus, the response speed may be much faster than that using the LED. Of course, it is possible to protect devices from external noise/surge. Since the present disclosure uses the SiC MOSFET 410 capable of high-speed switching at high frequency, the digital isolator 310 may be used because a SiC drive for controlling the SiC MOSFET 410 also has to have a corresponding response speed. The digital isolator 310 may perform a role similar to that of an opto-coupler, except that the digital isolator 310 should operate at high voltage and high frequency. The opto-coupler is an optical couple in which an LED and a phototransistor are combined in a device. The opto-coupler may transmit electrical signals using light, which can be important for noise countermeasure circuits, and may have a structure in which light reaches the phototransistor and turns on the transistor when only a voltage and electric current sufficient to turn on the LED therein are applied.

With digital isolators, digital signals may be sent across galvanic isolation boundaries and multiplexed digital channels may be easily obtained. In this context, even though the digital isolator 310 is a relatively expensive technology, it makes it possible to simplify the circuit configuration, and as a result, the net cost can be reduced.

Accordingly, the charging apparatus may be a solid state relay (SSR) in which internal circuits such as a control terminal and a load 500 terminal are isolated.

The charge pump 320 may be one of DC-DC converters, and a capacitor as an energy charge storage may be used to raise or lower the voltage.

In order for a MOSFET to operate, voltage needs be applied to the gate, and a dedicated driver for the SiC MOSFET 410 operating at high voltage and high frequency should be used to prevent malfunction of the gate.

For the SiC drive module 300, two power sources may be required for the digital isolator 310 and the charge pump 320. The power source for the digital isolator 310 may be a voltage between 1.5 V and 9 V while the power source for the charge pump 320 may be a voltage between 15 V and 25 V higher than that of the digital isolator 310, and an electric current of up to 110 mA may flow.

Referring to FIG. 4, the SiC MOSFET module 400 may include the heat sink 420 and a power connector 430. The SiC MOSFET 410 may be a central switching device of the SiC module 200. Voltage from drain to source may be up to 1200 V, and current may be up to 100 A. The SiC drive module 300 may transmit the driving signal S30 to the gate of the SiC MOSFET 410, and the ground level of the drive module may be connected to the source of the SiC MOSFET 410.

The heat sink 420 may reduce heat loss due to electric current from drain to source, and may consist of gas or liquid depending on the surrounding environment.

The power connector 430 may have a high voltage potential connected to the drain and a low voltage potential connected to the source side.

When the SiC MOSFET 410 is turned on, it may operate like a switch. To turn on the MOSFET, a gate signal may be required. The gate signal may be generated by a microcontroller, microcontroller unit (MCU), microprocessor, or any control system based on simple digital circuitry.

A controller 20 sends a trigger signal S10 to the digital isolator 310, and as the trigger signal S10 increases, the digital isolator 310 may send a signal to the charging pump circuit. As a result, the charge pump may provide an output signal to the SiC MOSFET 410. When the SiC MOSFET 410 receives the driving signal S30 from the SiC drive module 300, the power connector 430 is connected, and an electric current may flow from the drain to the source. This may be referred to as a first SiC module or a second SiC module.

The trigger signal S10 may be sent from the controller 20 to the SiC drive module 300 for switching of the SiC MOSFET 410, the driving operation of the SiC module 200 may be recognized by the controller 20 through a status signal S20, and the status signal S20 may be sent from the SiC drive module 300 to the controller 20.

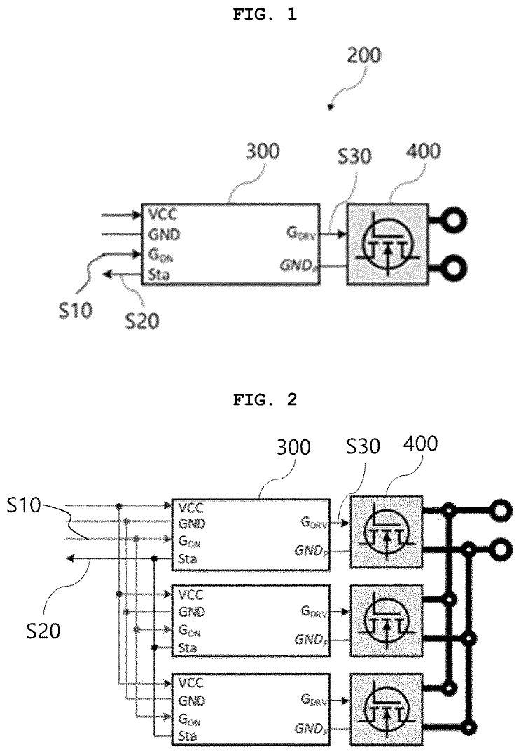

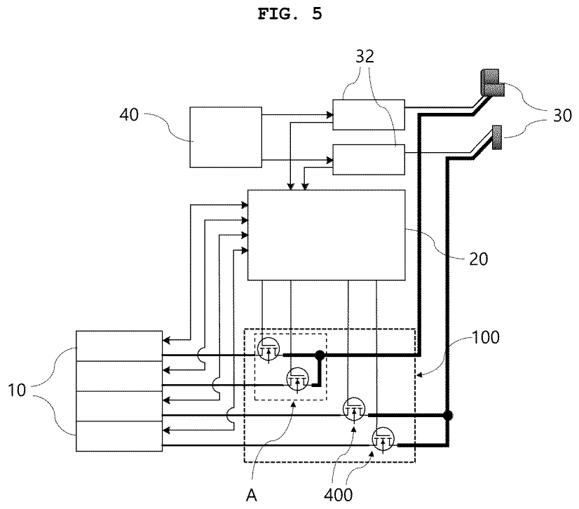

Referring to FIGS. 2 and 5, in the electric vehicle charging apparatus, the first SiC module or the second SiC module may be connected in parallel for higher current switching. This array SiC module may output various electric currents according to a combination of the first SiC module or the second SiC module through a relay mesh 100 while having a same voltage as the specific high voltage of the first SiC module or the second SiC module, and as a result, may output various power values. Accordingly, the array SiC module is connected to an external connector through the relay mesh 100, so that a user may select fast charging to suit his/her purpose. In this case, the first SiC module or the second SiC module may be connected in parallel to form the array SiC module, enabling rapid charging. All SiC drive modules 300 may be driven by the same trigger signal S10 for consistent operation. For example, when three first SiC modules or three second SiC modules are connected in parallel and connected to the external connector, the sub-loop circuit may have a maximum voltage of 1200 V and a maximum current of 300 A, so that an electric vehicle may be charged through the external connector with three times more current or power than in the case of one first SiC module or one second SiC module.

The SiC MOSFETs 410 in the relay mesh 100 may be provided with various specifications depending on circumstances. However, when the SiC MOSFETs 410 are configured identically, by installing the first SiC module or the second SiC module in parallel as described above, the relay mesh 100 composed of the array SiC MOSFET 410 may have an output value corresponding to an integer multiple of the output value of each SiC MOSFET 410. The integer may be a positive natural number.

As an example, for power distribution, the SiC MOSFET 410 may be turned on to connect one or two power packs 10 to the external connector 30. This may be one embodiment of the array SiC module, and various combinations may be possible depending on the user's selection of fast charging or slow charging. The power pack 10 may send DC current usable by an electric vehicle, and the vehicle may be charged through the external connector 30 according to the on/off of the SiC MOSFET 410. For example, the power pack 10 may be a 30 kW DC power source.

When a user selects the charging amount and a specific external connector 30 through a display unit 40, the controller 20 may send the trigger signal S10 to the SiC module according to a command such as fast charging or slow charging through a control board 32 connected to the external connector 30, and the SiC drive module 300 sends the driving signal S30 to the SiC MOSFET module 400, so that the SiC MOSFET 410 operates on/off. As such, the electric vehicle may be charged through the external connector 30 by a combination of the power of the power pack 10 connected to each SiC MOSFET 410 through the relay mesh 100.

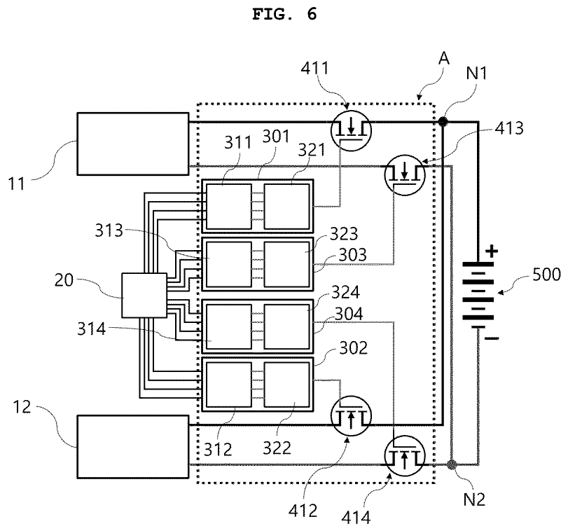

FIG. 6 is an enlarged view of part A shown in FIG. 5. A plurality of SiC modules may be provided in the relay mesh 100, and FIG. 6 may be one embodiment of possible combinations of various relay meshes 100.

Referring to FIG. 6, the power pack 10 is connected to the SiC MOSFET 410, and the SiC MOSFET 410 may be connected to the load 500 through the external connector 30. The load 500 may be an electric vehicle.

The SiC MOSFET 410 may be connected to a positive (+) terminal and a negative (−) terminal of each power pack 10 of a plurality of power packs 10.

The positive (+) terminal of a first power pack 11 is connected to a first SiC MOSFET 411, and electricity may be supplied from the first SiC MOSFET 411 to the load 500. Similarly, the positive (+) terminal of a second power pack 12 is connected to a second SiC MOSFET 412, and electricity may be supplied from the second SiC MOSFET 412 to the load 500.

The negative (−) terminal of the first power pack 11 is connected to a third SiC MOSFET 413, and electricity may be supplied from the load 500 to the third SiC MOSFET 413. Similarly, the negative (−) terminal of the second power pack 12 is connected to a fourth SiC MOSFET 414, and electricity may be supplied from the load 500 to the fourth SiC MOSFET 414.

Electricity passing through the individual SiC MOSFETs may be combined by a node and supplied to the load 500, and electricity passing through the load 500 may be divided by a node and supplied to the individual SiC MOSFETs. For example, electricity passing through the first SiC MOSFET 411 meets electricity passing through the second SiC MOSFET 412 at a first node N1 to be supplied to the load 500. Similarly, electricity from the load 500 may be branched from a second node N2 to the third SiC MOSFET 413 and the fourth SiC MOSFET 414 to flow.

When the first SiC MOSFET 411 is turned on and the third SiC MOSFET 413 is turned on, it can be regarded as a normal mode in which electricity from the first power pack 11 may be supplied to the load 500. Similarly, when the second SiC MOSFET 412 is turned on and the fourth SiC MOSFET 414 is turned on, it can be regarded as a normal mode in which electricity from the second power pack 12 may be supplied to the load 500.

For example, when only electricity from the first power pack 11 is required to be supplied to the load 500, the first SiC MOSFET 411 is turned on and the third SiC MOSFET 413 is turned on, while the second SiC MOSFET 412 and the fourth SiC MOSFET 414 are turned off, and then electricity from the first power pack 11 may be normally supplied to the load 500. However, when the third SiC MOSFET 413 fails or has a problem, the third SiC MOSFET 413 will be turned off, and the fourth SiC MOSFET 414 may be turned on instead, which can be regarded as a preliminary mode. Similarly, when only electricity from the second power pack 12 is required to be supplied to the load 500, the second SiC MOSFET 412 is turned on and the fourth SiC MOSFET 414 is turned on, while the first SiC MOSFET 411 and the third SiC MOSFET 413 are turned off, and then electricity from the power pack 12 may be normally supplied to the load 500. However, when the fourth SiC MOSFET 414 fails or has a problem, the fourth SiC MOSFET 414 will be turned off, and the third SiC MOSFET 413 may be turned on instead, which can be regarded as a preliminary mode. That is, the fourth SiC MOSFET 414 may be a spare SiC MOSFET of the first power pack 11, and the third SiC MOSFET 413 may be a spare SiC MOSFET of the second power pack 12.

Therefore, the SiC MOSFET connected to the negative (−) terminal of each power pack 10 may play a preliminary role in preparing for failure or defect of the SiC MOSFET connected to the positive (+) terminal.

Furthermore, even in the case of a normal mode in which the SiC MOSFETs connected to the positive and negative terminals of each power pack 10 are turned on, when two SiC MOSFETs are connected to each power pack 10, compared to the case where one SiC MOSFET is connected to each power pack 10, it is easier for an administrator to control since two SiC MOSFETs are used to obtain the desired pulse width modulation (PWM).

1. An electric vehicle charging apparatus comprising:
an external connector connected to an electric vehicle of a user; and
a relay mesh configured to supply electricity to the external connector,
wherein an amount of output power supplied through the relay mesh varies depending on a user's selection of fast charging or slow charging.

2. The electric vehicle charging apparatus of claim 1, wherein the relay mesh comprises a SiC module,
wherein the SiC module comprises:
a SiC MOSFET module serving as a switch for electricity supplied to the external connector; and
a SiC drive module sending a driving signal for switching to the SiC metal oxide semiconductor field-effect transistor (MOSFET) module.

3. The electric vehicle charging apparatus of claim 1, wherein a SiC drive module configured to send a driving signal for supplying electricity to the external connector is provided,
wherein the SiC drive module comprises:
a digital isolator that physically separates the SiC drive module from other circuits; and
a charge pump serving as a DC-DC converter.

4. The electric vehicle charging apparatus of claim 1, wherein a SiC metal oxide semiconductor field-effect transistor (MOSFET) module configured to supply electricity to the external connector by switching is provided,
wherein the SiC MOSFET module comprises:
a heat sink that reduces heat loss from the SiC MOSFET module;
a power connector to which electricity supplied to the external connector is connected; and
a SiC MOSFET that is turned on when electricity is supplied to the external connector and turned off when not supplied,
wherein the SiC MOSFET uses silicon carbide (SiC) as a semiconductor device material.

5. The electric vehicle charging apparatus of claim 1, wherein a display unit where the user selects fast charging or slow charging is provided,
wherein a signal according to the user's selection is sent to a control board, and the control board sends an operation signal to the external connector selected by the user and a controller,
wherein the controller controls the amount of power sent to the external connector by sending a trigger signal to the relay mesh according to the operation signal.

6. The electric vehicle charging apparatus of claim 1, wherein the relay mesh is provided with a first SiC module and a second SiC module,
wherein a power pack for supplying DC electricity for electric vehicle charging to the first SiC module and the second SiC module is provided, and an array SiC module in which the first SiC module and the second SiC module are connected in parallel is provided,
wherein the array SiC module outputs a positive integer multiple of an amount of power output from each SiC module.

7. The electric vehicle charging apparatus of claim 1, wherein power packs are provided to supply DC electricity for electric vehicle charging to a SiC module,
SiC metal oxide semiconductor field-effect transistors (MOSFETs) are connected to the positive (+) terminals and negative (−) terminals of the power packs, and
control of pulse width modulation (PWM) is fed back by the SiC MOSFETs.

8. The electric vehicle charging apparatus of claim 1, wherein the power packs are provided to supply DC electricity for electric vehicle charging to a SiC module,
wherein a positive (+) terminal of a first power pack is connected to a first SiC MOSFET, and electricity is supplied from the first SiC metal oxide semiconductor field-effect transistor (MOSFET) to a load,
a positive (+) terminal of a second power pack is connected to a second SiC MOSFET, and electricity is supplied from the second SiC MOSFET to the load,
a negative (−) terminal of the first power pack is connected to a third SiC MOSFET, and electricity is supplied from the load to the third SiC MOSFET,
a negative (−) terminal of the second power pack is connected to a fourth SiC MOSFET, and electricity is supplied from the load to the fourth SiC MOSFET,
electricity passing through the first SiC MOSFET and the second SiC MOSFET is combined at a first node and supplied to the load, and
electricity passing through the load is branched at a second node and supplied to the third SiC MOSFET and the fourth SiC MOSFET,
wherein when the first SiC MOSFET and the third SiC MOSFET are turned on to supply electricity from the first power pack to the load, and when the second SiC MOSFET and the fourth SiC MOSFET are turned on to supply electricity from the second power pack to the load, it is regarded as a normal mode.

9. The electric vehicle charging apparatus of claim 1, wherein the power packs are provided to supply DC electricity for electric vehicle charging to a SiC module,
wherein a positive (+) terminal of a first power pack is connected to a first SiC metal oxide semiconductor field-effect transistor (MOSFET), and electricity is supplied from the first SiC MOSFET to a load,
a positive (+) terminal of a second power pack is connected to a second SiC MOSFET, and electricity is supplied from the second SiC MOSFET to the load,
a negative (−) terminal of the first power pack is connected to a third SiC MOSFET, and electricity is supplied from the load to the third SiC MOSFET,
a negative (−) terminal of the second power pack is connected to a fourth SiC MOSFET, and electricity is supplied from the load to the fourth SiC MOSFET,
electricity passing through the first SiC MOSFET and the second SiC MOSFET is combined at a first node and supplied to the load, and
electricity passing through the load is branched at a second node and supplied to the third SiC MOSFET and the fourth SiC MOSFET,
wherein when the first SiC MOSFET and the fourth SiC MOSFET are turned on and the third SiC MOSFET is turned off in case a defect occurs in the third SiC MOSFET, it is regarded as a preliminary mode,
wherein in the preliminary mode, the SiC MOSFET connected to the negative terminal of one power pack becomes a spare MOSFET of the SiC MOSFET connected to the negative terminal of another power pack.
